(19) United States
(12) Patent Application Publication
(10) Pub. No.: US 2013/0093029 A1
(43) Pub. Date: Apr. 18, 2013

(54) PROCESS FOR PREPARING A BERYLLIUM OXIDE LAYER ON A SEMICONDUCTOR SUBSTRATE

(71) Applicants: Jung Hwan YUM, Austin, TX (US); Gennadi Bersuker, Austin, TX (US); K. Sanjay Banerjee, Austin, TX (US)

(72) Inventors: Jung Hwan YUM, Austin, TX (US); Gennadi Bersuker, Austin, TX (US); K. Sanjay Banerjee, Austin, TX (US)

(73) Assignee: SEMATECH, INC., Albany, NY (US)

(21) Appl. No.: 13/271,522

(22) Filed: Oct. 12, 2011

(51) Int. Cl. H01L 21/316; H01L 29/78; H01L 29/12

(52) U.S. Cl. 257/410; 438/778; 257/632; 257/E21.271; 257/E29.068; 257/E29.255

(57) ABSTRACT

A process for creating a beryllium oxide film on the surface of a semiconductor material is disclosed. The process is useful for making gate dielectric layers for metal-oxide-semiconductor (MOS) devices, particularly III-V semiconductor devices.

### TECHNICAL FIELD

The invention relates to semiconductor devices and device fabrication. Specifically, the invention relates to gate dielectric layers for metal-oxide-semiconductor (MOS) devices and their method of fabrication. To that end, the present invention is directed towards a process for creating a beryllium oxide film on the surface of a semiconductor material.

### BACKGROUND OF THE INVENTION

The high electron mobility exhibited in III-V semiconductors makes them attractive for use as a channel material in metal/oxide/semiconductor (MOS) transistors. One of the main challenges in fabricating a III-V MOSFET is the lack of thermodynamically stable insulators of high electrical quality, which would passivate the interface states at the dielectric/substrate interface and unpin the Fermi level. To address this issue, various dielectrics, such as Si/SiO₂, Ge, SiGe, SiN and Al₂O₃, have been considered as interface passivation layers (IPL). The high dielectric constant and interface quality of atomic layer deposited (ALD) Al₂O₃ make it superior to the other foregoing candidates for IPL. However, defect density in Al₂O₃ remains high enough to limit its performance in III-V MOSFETs, so that it is reasonable to contemplate alternatives.

An improved IPL would exhibit as many as possible of the following attributes: 1. It would have high thermal stability (determined by the material's Gibb's free energy) 2. It would exhibit a large energy band gap. 3. It would act as an efficient diffusion barrier to prevent the gate dielectric contamination by the III-V channel materials. 4. It would exhibit a low density of structural defects at the interface. 5. It would exhibit low phonon scattering.

U.S. Pat. No. 4,451,499 to Morimoto et al. described physical vapor deposition method to deposit a beryllium oxide (BeO) film on glass plates, sapphire and sodium chloride substrates. In the '499 patent, BeO is deposited using the reaction between metallic beryllium vapor and oxygen. Because BeO appears to have some desirable properties, one might consider using it as an IPL. However the Morimoto process requires high vacuum (10⁻⁵ Torr) and high heating temperature (1,300° C.-1,400° C.) to evaporate metallic beryllium. The result of the high kinetic energy of the Be atoms in the Morimoto physical vapor deposition (PVD) process is that the energetic Be atoms penetrate quite deeply into the substrate and the resulting devices work poorly or not at all.

### SUMMARY OF THE INVENTION

The physical and electrical properties of beryllium oxide (BeO) suggest that it would useful as an IPL. BeO has excellent thermal stability consistent with the value of its Gibbs free energy. The energy band-gap of bulk BeO is 10.6 eV, which is among the largest commonly encountered, and its dielectric constant is around 6.8, which is very close to that of atomic layer deposited aluminum oxide. Beryllium does not have d orbitals, which may make it less prone to forming defects in the crystalline metal oxide. Beryllium oxide has a very short beryllium-oxygen bond length and dense structure with small interstitial spaces as well as a strong covalent bonding (due to the similar electronegativity of beryllium and oxygen). The thermal conductivity of BeO at room temperature is 300 W·m−1K−1 compared to 35 W·m−1K−1 for Al₂O₃. Thus, if it can be applied in a discrete, well-ordered film, beryllium oxide provides an excellent interface passivation layer.

A solution has now been found to the problem of creating a good BeO film on a semiconductor substrate—particularly a III-V semiconductor substrate.

In one aspect, the invention relates to a process for forming a beryllium oxide film on a substrate. The process comprises the sequential steps of:

(a) providing a substrate in a reaction chamber;
(b) exposing the substrate to a dialkylberyllium or dihaloberyllium compound;
(c) exposing the substrate to a source of oxygen,
steps (b) and (c) comprising a single cycle,
whereby the dialkylberyllium compound and the source of oxygen react to form a beryllium oxide film on the substrate.

In another aspect, the invention relates to an electronic device. The device comprises a IV or III-V semiconductor material substrate having disposed thereon a film comprising beryllium oxide, thereby creating a beryllium oxide-semiconductor interface. The BeO/substrate interface produced by the foregoing process is characterized by its sharpness, wherein the concentration in atom percent of beryllium 5 nm below the beryllium oxide-semiconductor interface is below 1%.

In another aspect, the invention relates to A transistor comprising: a body region between first and second source/drain regions in a IV or III-V semiconductor material substrate and a beryllium oxide-containing film on said body region, having a beryllium oxide-semiconductor interface therebetween, wherein the concentration in atom percent of beryllium 5 nm below the beryllium oxide-semiconductor interface is below 1%.

### BRIEF DESCRIPTION OF THE DRAWINGS

These and other aspects, features, and advantages of the present invention will become apparent upon further consideration of the following detailed description of the invention when read in conjunction with the drawing figures, in which:

FIG. 1 depicts an atomic layer deposition system for processing of a BeO film in accordance with the present invention.

FIG. 2 depicts a flow diagram of elements of a process for forming a BeO film in accordance with the present invention.

FIG. 3 is a plot of capacitance versus gate voltage for a BeO film on silicon substrate made by the process of Morimoto.

FIG. 4 is a plot of capacitance versus gate voltage for a BeO film on silicon substrate made by the process of the invention.

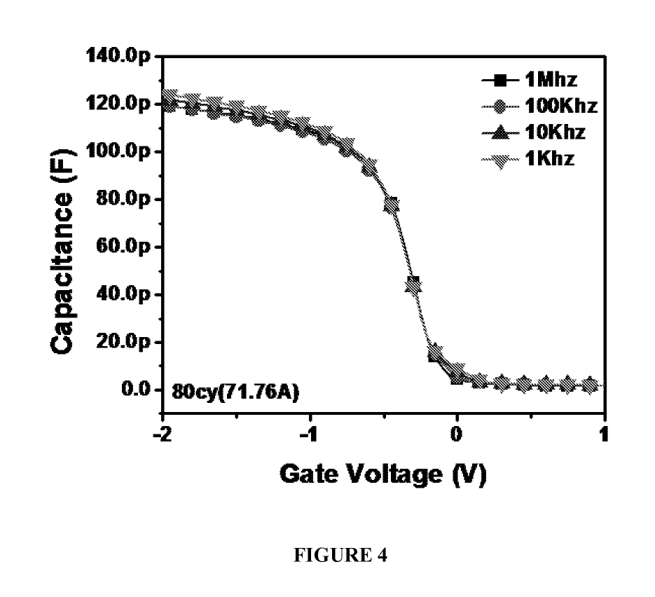

### DETAILED DESCRIPTION OF THE INVENTION

In a process aspect, the invention relates to a process for forming a beryllium oxide film on a substrate. As noted above the process comprises the sequential steps of: (a) providing a substrate in a reaction chamber; (b) exposing the substrate to a dialkylberyllium or dihaloberyllium compound; and (c) exposing the substrate to a source of oxygen. Steps (b) and (c) comprise a single cycle. The dialkylberyllium compound and the source of oxygen react to form a beryllium oxide film on the substrate. Steps (b) and (c) may be repeated to provide a plurality of cycles, and the thickness of the BeO film may be easily controlled the number of cycles.

The process described herein, in which film thickness depends only on the number of reaction cycles, ensures good thickness control and stoichiometry. High vacuum and temperature are not required, resulting in shorter process time and cost reduction. In addition, deposition of different multilayer structures is straightforward. These advantages make the method attractive for the manufacturing of future generations of integrated circuits. Other advantages of the method are high density and low impurity level in the deposited film. In addition, the process is “self-cleaning” and minimizes native oxides on the surface of the III-V substrate.

The substrate may be a semiconductor. The semiconductors that are the substrates for the process of the invention are known in the art as IV and III-V semiconductors. The process described herein was developed to surmount problems in preparing BeO films on III-V semiconductors, but it is superior to known processes for preparing BeO films on IV semiconductors as well. Examples of common IV semiconductors are silicon, germanium and silicon-germanium. Examples of common III-V semiconductors are GaAs, InP, InAs, GaP, InGaAs, InAlAs, InAlGa and GaInP. Examples of other, less common binary and ternary III-V materials include: AlSb, GaSb, GaP, InSb, AlGaAs, GaAsP, InGaN. For some uses quaternary III-V materials, such as AlGaInP and InGaAsSb, can be employed. The binary semiconductors GaAs, InP, InAs, GaP and ternary and quaternary alloys of GaAs, InP, InAs and GaP are preferred. The InAs/GaAs ternary alloy can be characterized as InₓGa₁₋ₓAs where x is the proportion of InAs and 1-x is the proportion of GaAs. A convenient substrate for InₓGa₁₋ₓAs is InP. Since InₓGa₁₋ₓAs with 53% InAs has the same lattice constant as InP, the combination leads to very high quality thin films, and InₓGa₁₋ₓAs with 53% InAs is often called “standard InGaAs” without bothering to note the values of “x” or “1-x”.

The beryllium source is a dialkylberyllium or dihaloberyllium compound. Dimethyl beryllium is preferred; diethylberyllium can also be used. Dichloroberyllium is less preferred because it has a higher sublimation temperature, as a result of which, common atomic layer deposition tools that would be required to use BeCl₂ are not currently as readily available. An advantage that arises from the use of dialkylberyllium or dihaloberyllium compounds in atomic layer deposition is a phenomenon called “self-cleaning”. Self cleaning depends on the chemical structure of the beryllium source. The self-cleaning phenomenon does not appear to occur in PVD deposition of beryllium or beryllium oxide. In atomic layer deposition of beryllium oxide from the BeO precursors described herein, it appears that the precursor, e.g. Be(CH₃)₂, absorbs oxygen from the native oxides such as Ga—O, As—O and In—O due to high reactivity of the methyl ligand, CH₃. It is presumed that the ethyl ligand and the chlorine ligand will behave similarly.

The oxygen source may be O₂ gas, O₃ gas or H₂O. The term “source of oxygen” refers to these compounds and other gaseous compounds that contain oxygen that can react with beryllium to form beryllium oxide under the conditions of the deposition.

The substrate in the reaction chamber may be maintained at a temperature between 25° C. and 300° C. In some embodiments the temperature is between 200° C. and 300° C. The pressure may be maintained between 0.05 mTorr and 0.1 Torr. In some embodiments the pressure is between 0.1 mTorr and 20 mTorr.

Annealing, which is optional, is commonly carried out in an inert atmosphere such as argon, at temperatures from 300° C. to 1100° C. In certain embodiments the substrate with the BeO film on it may be annealed at a temperature between 400° C. and 1000° C. for a period of 10 seconds to 60 minutes. In some embodiments, it is annealed between 400° C. and 600° C. for a period of 10 seconds to 5 minutes. The expression “from 300° C. to 1100° C.” (and analogously other ranges) means that the process is carried out either by maintaining any temperature between 300° C. and 1100° C. or by varying the temperature within that range.

In one embodiment the process comprises the sequential steps of:

(a) providing a substrate in a reaction chamber at a temperature between 200° C. and 300° C. and a pressure between 0.05 mTorr and 2 mTorr;
(b) exposing the substrate to a dialkylberyllium compound in an inert carrier gas for a period from 0.001 second to 2.0 seconds;
(c) purging the chamber with an inert carrier gas;
(d) exposing the substrate to a source of oxygen in an inert carrier gas for a period from 0.001 second to 1.0 seconds; and
(e) purging the chamber with an inert carrier gas.
In this embodiment steps (b) through (e) comprise a single cycle, and the cycle may be repeated. The dialkylberyllium may be dimethylberyllium, the source of oxygen may be H₂O, and the inert carrier gas may be nitrogen or argon. In each cycle, the exposure of the dialkylberyllium compound in an inert carrier gas may be carried out for a period from 0.1 second to 0.5 seconds, the exposure of the substrate to a source of oxygen in an inert carrier gas may be carried out for a period from 0.01 second to 0.1 seconds and the purges may be carried out for from 1 second to 5 seconds.

In general, a BeO film may be formed on a substrate mounted in a reaction chamber by pulsing a beryllium containing precursor into the reaction chamber followed by pulsing an oxygen containing precursor. Between each pulsing, a purging gas is introduced into the reaction chamber. Pulsing a beryllium containing precursor into the reaction chamber followed by pulsing an oxygen containing precursor with subsequent purging after each pulsing constitutes a cycle. Different purging gases can be employed for the beryllium sequence; nitrogen and argon are convenient. Furthermore, pulsing each precursor into the reaction chamber may be individually controlled for a predetermined period, where the predetermined period for each precursor may differ according to the nature of the precursor.

Each cycle deposits a BeO layer. The thickness of the BeO layer on each cycle will depend on the precursors used, the period of the pulses, and the processing temperature. A BeO film with a predetermined thickness is formed by repeating the cycle to achieve the desired thickness. Once a BeO film with the desired thickness is formed, the BeO film can be annealed.

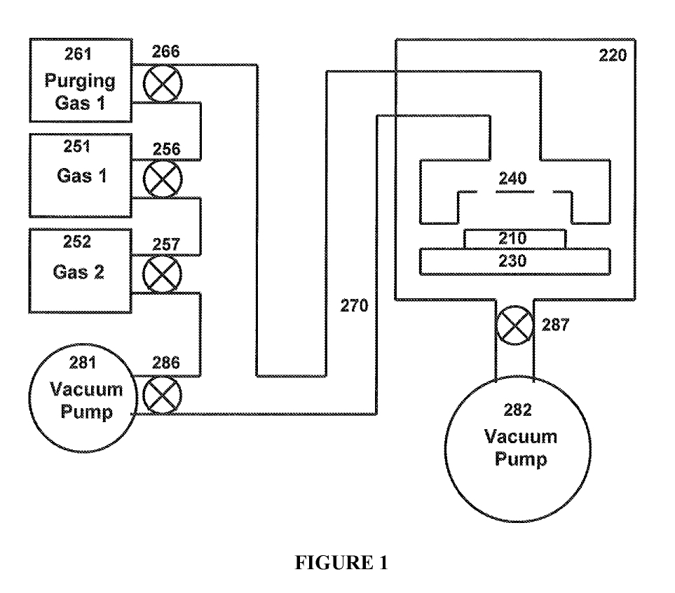

FIG. 1 depicts elements of an atomic layer deposition system for processing a BeO film in accordance with the present invention. In FIG. 1, a substrate 210 is placed inside a reaction chamber 220 of the ALD system. Also located within the reaction chamber 220 is a heating element 230, which is thermally coupled to substrate 210 to control the substrate temperature. A gas distribution fixture 240 introduces precursor gases to the substrate 210. Each precursor gas originates from individual gas sources 251, 252 whose flow is controlled by mass flow controllers 256, 257, respectively. The gas sources 251-252 provide a precursor gas either by storing the precursor as a gas or by providing a location and apparatus for evaporating a solid or liquid material to form the selected precursor gas.

Also included in the ALD system are purging gas source 261, which is coupled to mass-flow controller 266. The gas sources 251-252 and the purging gas source 261 are coupled by their associated mass-flow controllers to a common gas line or conduit 270 which is coupled to the gas distribution fixture 240 inside the reaction chamber 220.

Gas conduit 270 is also coupled to a first vacuum pump, or exhaust pump, 281 by mass flow controller 286 to remove excess precursor gases, purging gases, and by-product gases at the end of a purging sequence from the gas conduit.

A second vacuum pump, or exhaust pump, 282 is coupled by mass-flow controller 287 to remove excess precursor gases, purging gases, and by-product gases at the end of a purging sequence from the reaction chamber 220. For convenience, control displays, mounting apparatus, temperature sensing devices, substrate maneuvering apparatus, and necessary electrical connections as are known to those skilled in the art are not shown in FIG. 1.

The use, construction and fundamental operation of reaction chambers for deposition of films are understood by those of ordinary skill in the art of semiconductor fabrication. The present invention may be practiced on a variety of such reaction chambers without undue experimentation. Furthermore, one of ordinary skill in the art will comprehend the necessary detection, measurement, and control techniques in the art of semiconductor fabrication upon reading the disclosure.

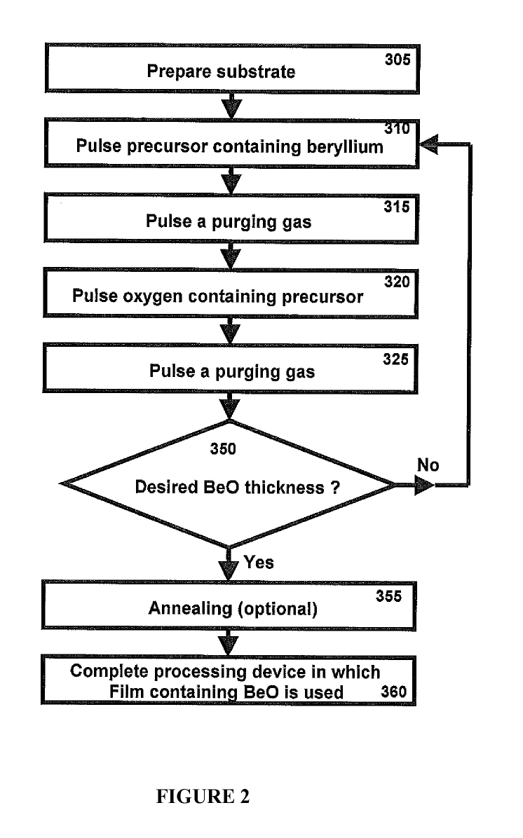

FIG. 2 depicts a flow diagram of elements of a method to process a BeO film. The method can be implemented with the atomic layer deposition system of FIG. 1. At 305, a substrate is prepared. The substrate used for forming a transistor is typically a one of the IV or III-V semiconductors described above. The preparation process includes cleaning of the substrate 210 and forming layers and regions of the substrate, such as drains and sources of a metal oxide semiconductor (MOS) transistor, prior to forming a gate dielectric. The sequencing of the formation of the regions of the transistor being processed follows typical sequencing that is generally performed in the fabrication of a MOS transistor as is well known to those skilled in the art. Included in the processing prior to forming a gate dielectric is the masking of substrate regions to be protected during the gate dielectric formation. In this embodiment, the unmasked region includes a body region of a transistor, but one skilled in the art will recognize that other semiconductor device structures may utilize this process, Additionally, the substrate 210 in its ready for processing form is conveyed into a position in reaction chamber 220 for ALD processing.

At 310, a precursor containing beryllium is pulsed into reaction chamber 220. The substrate may be heated to a temperature of between 200° C. and 300° C. In particular, Be(CH₃)₂ may be used as a source material. The Be(CH₃)₂ is pulsed into reaction chamber 220 through the gas distribution fixture 240 onto substrate 210. The flow of the Be(CH₃)₂ is controlled by mass flow controller 256 from gas source 251. The Be(CH₃)₂ gas can be provided by evaporation from an open crucible held at about 130° C., and provided to the gas source 251. The Be(CH₃)₂ reacts with the surface of the substrate 210 in the desired region defined by the unmasked areas of the substrate 210.

At 315, a first purging gas is pulsed into the reaction chamber 220. In particular, nitrogen with a purity greater than 99.9% may be used as a purging gas and a carrier gas for Be(CH₃)₂. The nitrogen flow is controlled by mass flow controller 266 from the purging gas source 261 into the gas conduit 270. Following the purge, at 320, a first oxygen containing precursor is pulsed into the reaction chamber 220. For the beryllium sequence using Be(CH₃)₂ as the precursor, water is selected as the precursor acting as an oxidizing reactant to form a beryllium oxide on the substrate 210. The oxygen-source gas is pulsed into the reaction chamber 220 through gas conduit 270 from gas source 252 by mass-flow controller 257. The water aggressively reacts at the surface of substrate 210. Following the pulsing of oxidizing reactant water at 325, the purging gas is injected into the reaction chamber 220. In the Be(CH₃)₂/water sequence, nitrogen gas is used to purge the reaction chamber after pulsing each precursor gas. Excess precursor gas and reaction by-products are removed from the system by the purge gas in conjunction with the exhausting of the reaction chamber 220 using vacuum pump 282 through mass flow controller 287, and exhausting of the gas conduit 270 by the vacuum pump 281 through mass flow controller 286.

During the Be(CH₃)₂/water sequence, the substrate is held between about 200° C. and about 300° C. by the heating element 230 with the reaction chamber having a reduced pressure near the substrate of 0.2-0.3 mTorr. The Be(CH₃)₂ pulse time may range from about 0.01 seconds to about 0.5 seconds. One embodiment uses a Be(CH₃)₂ pulse time of 0.4 sec. The purge pulses may range from about 1 sec to about 5 sec. The water pulse times may range from about 0.01 sec to about 0.1 sec, with one embodiment employing a 0.015 sec water pulse time.

The thickness of a BeO film after one cycle is determined by the pulsing periods used in the beryllium sequence at a given temperature. The pulsing periods of the ALD process depend upon the characteristics of the reaction system employed and the precursor and purging sources. Typically, at a given temperature, the pulsing periods can vary over a significant range above some minimum pulse time for the precursors, without substantially altering the growth rate. Once a set of periods for one cycle is determined, the growth rate for the BeO film will be set at a value such as N nm/cycle. For a desired BeO film thickness, t, in an application such as forming a gate dielectric of a MOS transistor, the ALD process would be repeated for t/N cycles.

At 350, it is determined whether the BeO film is of the desired thickness, t. As mentioned, the desired thickness should be completed after t/N cycles. If less than t/N cycles have been completed, the process starts over at 310 with the pulsing of the precursor containing beryllium, which in the embodiment discussed above is a Be(CH₃)₂ gas. If t/N cycles have completed, no further ALD processing is required and the BeO film, at 355, may be annealed, although annealing is optional. At 360, processing the device containing the BeO film is completed. In one embodiment, completing the device includes completing the formation of a transistor. Using this method, the BeO may be deposited directly on the substrate without use of a seed layer.

The terms wafer and substrate used in the foregoing and following descriptions include any structure having an exposed surface with which to form an integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductors, as well as other semiconductor structures well known to one skilled in the art.

The terminology “below the beryllium oxide-semiconductor interface” is intended to mean into the semiconductor on the semiconductor side of the interface, regardless of actual orientation of the device. Most commonly, the semiconductor will be mounted in the ALD tool such that the interface between the BeO and the semiconductor will be formed on the top surface of the semiconductor, and “below the interface” will indeed be below in a spatial sense, but other orientations of the workpiece are theoretically possible. When beryllium oxide is deposited by the PVD process described in the art, the kinetic energy of the PVD drives the beryllium atoms deeply into the substrate. We have measured penetration of Be atoms to 5 nm into an SiO₂ layer when Be atoms are PVD deposited on SiO₂(5 nm)/Si substrate using sputtering at low power. In contrast, when the process of the invention is used, the concentration in atom percent of beryllium 5 nm below the beryllium oxide-semiconductor interface is below 1%. The result of these differences is that BeO produced by physical vapor deposition process provides devices that function poorly when the substrate is silicon, and devices that fail entirely when the substrate is a III-V semiconductor.

Dialkylberyllium compounds are not commercially available at present. Dimethylberyllium (Be(CH₃)₂) for use in the processes described herein was synthesized from BeCl₂ by the method described by Gilman and Schulze [J. Chem. Soc. 1927, 2663]. Methyl magnesium bromide (CH₃MgBr, 2.5 M in diethyl ether was added drop wise over a period of 10 min to a rapidly stirred solution of BeCl₂ in anhydrous ether cooled to −30° C. After stirring the resulting slurry for 12 hours, the solvent was removed under reduced pressure. The residual colorless solid was then extracted with benzene and filtered to remove precipitated magnesium salts. Subsequent removal of the residual benzene under reduced pressure afforded Be(CH₃)₂ solvated with approximately 2.5 molar equivalents of Et₂O. Multiple rounds of sublimation and preheating below the sublimation temperature were successful in removing the residual Et₂O, which resulted in improved ALD BeO gate dielectrics on III-V and Si.

MOS capacitors were fabricated on both p-type Si and GaAs substrates each with doping concentrations of around 5×10¹⁷/cm³. After hydrofluoric acid (HF) surface cleaning, 5 to 10 nm ALD BeO was deposited at 200° C. using a Nano Cambridge ALD module. Beryllium oxide was deposited using dimethylberyllium and water for reagents. For control samples, atomic layer deposited Al₂O₃ MOS capacitors were also fabricated using trimethylaluminum and water under the same conditions. Physical thickness was measured by ellipsometry with various wavelengths and vertical angles between 45° and 75° and confirmed by transmission electron microscopy. Post-deposition annealing in the range of 500° C. to 600° C. was performed by rapid thermal annealing in nitrogen ambient for 30 sec-3 min, followed by reactively sputtered TaN (2000 Å) as the gate electrode. After patterning and etching, post metal-deposition annealing was done at 400° C. for 3 min in the forming gas ambient.

X-ray photoelectron spectroscopy (XPS) data of BeO grown on a GaAs substrate showed that the Ga—O and As—O signals were reduced after dimethylberyllium deposition, demonstrating that the dimethylberyllium has excellent self-cleaning properties—comparable with trimethylaluminum. It appears that dimethylberyllium efficiently absorbs oxygen from the GaAs native oxide.

Atomic Force Microscopy of 5 nm ALD BeO and Al₂O₃ respectively grown on GaAs surfaces with the HF treatment showed that the BeO surface exhibited a low root mean square roughness of 0.194 nm.

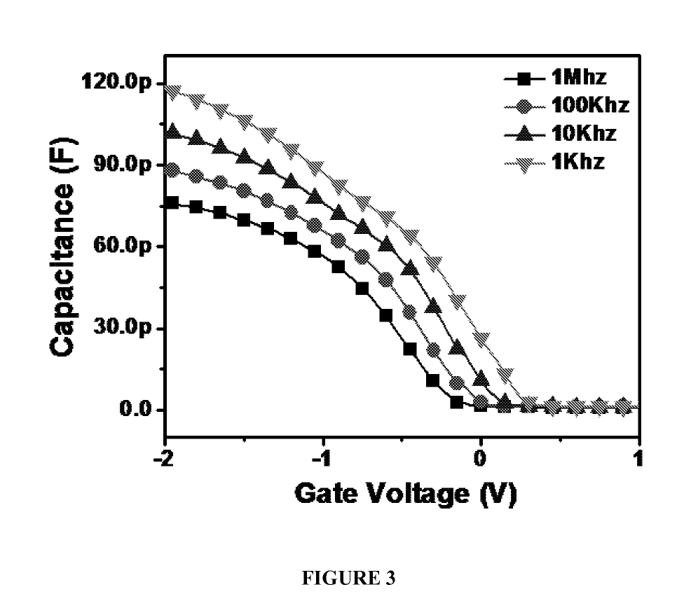

Capacitance as a function of gate voltage for the layers formed by the two different processes were compared. The results are shown in FIGS. 3 (PVD) and 4 (process of the invention). It can be seen that the capacitance of the BeO film varies by less than 10% as a function of frequency at gate voltage below −1 for the films made by the process described herein and greater than 10% for the films made by the PVD process described in the art. It should be further noted this comparison could only be carried out on devices obtained from BeO deposition on silicon; BeO deposited on GaAs by PVD did not provide functional layers whose capacitance could be measured.

The use of BeO gate dielectric on InP MOSCAPs and MOSFETs was also demonstrated.

MOSCAPs were fabricated on n-type InP (100) with doping concentrations of approximately 5×10¹⁷/cm³. After 1% HF dip surface cleaning, S passivation was performed by dipping in a 20% (NH₄)₂S solution at room temperature for 10 min. Using this process, 50-120 Å BeO was deposited as a gate dielectric at 250° C. using dimethylberyllium and H₂O as the precursors. As a reference, a similar thickness of Al₂O₃ was also deposited by ALD using trimethylaluminum and H₂O as the precursors. Then, post-deposition annealing in the range of 500-550° C. was performed by a rapid thermal annealing under nitrogen ambient for 30-60 s. In these devices, physical vapor deposited (PVD) TaN was used for gate electrode. After patterning and etching, post metallization annealing was performed at 450° C. for 3 min in a forming gas ambient. Then, e-beam evaporated AuGe/Ni/Au alloy was used as the backside contact.

The n-channel MOSFETs were fabricated on semi-insulating InP (100) substrate with a ring-type pattern by a gate last process. The same surface treatment was performed on semi-insulating InP as MOSCAPs, and then approximately 100 Å Al₂O₃ as a dummy gate oxide was deposited by ALD 250° C. After 35 keV, 5×10¹⁴/cm² Si ion implantation at the source and drain regions, samples were annealed at 730-770° C. for 15 s for S/D activation. Then, Al₂O₃ layer was removed using buffered oxide etchant. After the same surface treatment on these InP samples, 90 cycles (110-120 Å) ALD BeO was deposited as a gate dielectric. The TaN gate electrode was deposited by reactive sputtering. Finally, for source and drain metallization, around 600 Å of AuGe/Ni/Au was deposited using e-beam evaporation. High-resolution cross-sectional transmission electron microscopy showed that the interface between BeO and InP remained atomically sharp without any sign of interfacial reaction after PDA at 500° C. for 1 min. The use of BeO prepared by the ALD process described herein results in excellent interface quality on InP substrates, thin interfacial native oxide, high thermal stability, and positive threshold voltage.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. It is to be understood that the above description is intended to be illustrative, and not restrictive. Combinations of the above embodiments and other embodiments will be apparent to those of skill in the art upon reviewing the above description. The scope of the invention should be determined with reference to the appended claims, along with the full scope of equivalents to which such claims are entitled.

1. A process for forming a beryllium oxide film on a substrate comprising the sequential steps of:
(a) providing a substrate in a reaction chamber;
(b) exposing said substrate to a dialkylberyllium or dihaloberyllium compound;
(c) exposing said substrate to a source of oxygen,
steps (b) and (c) comprising a single cycle,
whereby said dialkylberyllium compound and said source of oxygen react to form a beryllium oxide film on said substrate.

2. A process according to claim 1 wherein said substrate in said chamber is maintained at a temperature between 200° C. and 300° C. at least following step (c).

3. A process according to claim 1 wherein said substrate is a IV or III-V semiconductor material.

4. A process according to claim 1 wherein steps (b) and (c) are repeated to provide a plurality of cycles.

5. A process according to claim 1 wherein said dialkylberyllium is dimethylberyllium or diethylberyllium.

6. A process according to claim 1 wherein said source of oxygen is chosen from O₂ gas, O₃ gas and H₂O.

7. A process according to claim 6 wherein said source of oxygen is H₂O.

8. A process according to claim 1 wherein said substrate is chosen from Si, Ge, SiGe, GaAs, InP, InAs, GaP and ternary and quaternary alloys of GaAs, InP, InAs and GaP.

9. A process according to claim 8 wherein said substrate is chosen from InGaAs and GaAs.

10. A process according to claim 1 for forming a beryllium oxide film on a IV or III-V semiconductor material substrate comprising the sequential steps of:
(a) providing a substrate in a reaction chamber at a temperature between 200° C. and 300° C. and a pressure between 0.05 mTorr and 2 mTorr;
(b) exposing said substrate to a dialkylberyllium compound in an inert carrier gas for a period from 0.001 second to 2.0 seconds;
(c) purging said chamber with an inert carrier gas;
(d) exposing said substrate to a source of oxygen in an inert carrier gas for a period from 0.001 second to 1.0 seconds;
(e) purging said chamber with an inert carrier gas,
steps (b) through (e) comprising a single cycle, and
optionally carrying out addition cycles;
whereby said dialkylberyllium compound and said source of oxygen form a beryllium oxide film on said substrate.

11. A process according to claim 10 additionally comprising annealing said beryllium oxide film at a temperature of 400° C. to 600° C. for a period of 10 seconds to 5 minutes.

12. A process according to claim 10 wherein said dialkylberyllium is dimethylberyllium, said source of oxygen is H₂O, said inert carrier gas is nitrogen or argon, and, in each cycle, said exposing a dialkylberyllium compound in an inert carrier gas is carried out for a period from 0.1 second to 0.5 seconds, said exposing said substrate to a source of oxygen in an inert carrier gas is carried out for a period from 0.01 second to 0.1 seconds and said purges are carried out for from 1 second to 5 seconds.

13. An electronic device, comprising a IV or III-V semiconductor material substrate having disposed thereon a film comprising beryllium oxide, said substrate and said beryllium oxide film forming a beryllium oxide-semiconductor interface, wherein the concentration of beryllium 5 nm below the beryllium oxide-semiconductor interface is below 1 atom percent.

14. The electronic device of claim 13 wherein the substrate is chosen from Si, Ge, SiGe, GaAs, InP, InAs, GaP and ternary and quaternary alloys of GaAs, InP, InAs and GaP.

15. The device according to claim 14 wherein said substrate comprises InGaAs or GaAs.

16. A transistor comprising: a body region between first and second source/drain regions in a IV or III-V semiconductor material substrate and a beryllium oxide-containing film on said body region, having a beryllium oxide-semiconductor interface therebetween, wherein the concentration in atom percent of beryllium 5 nm below the beryllium oxide-semiconductor interface is below 1 atom percent.

17. The transistor of claim 16 wherein the substrate is chosen from Si, Ge, SiGe, GaAs, InP, InAs, GaP and ternary and quaternary alloys of GaAs, InP, InAs and GaP.

18. The transistor according to claim 17 wherein said substrate comprises InGaAs or GaAs.
